(19) United States
(12) Patent Application Publication
(10) Pub. No.: US 2024/0128174 A1
(43) Pub. Date: Apr. 18, 2024

(54) SEMICONDUCTOR PACKAGE

(71) Applicant: Samsung Electronics Co., Ltd., Suwon-si (KR)

(72) Inventors: Choongbin Yim, Suwon-si (KR); Gitae Park, Suwon-si (KR); Jongbo Shim, Suwon-si (KR)

(73) Assignee: Samsung Electronics Co., Ltd., Suwon-si (KR)

(21) Appl. No.: 18/380,424

(22) Filed: Oct. 16, 2023

(30) Foreign Application Priority Data
Oct. 18, 2022 (KR) 10-2022-0134068
May 18, 2023 (KR) 10-2023-0064512

(51) Int. Cl. H01L 23/498; H01L 23/00; H01L 23/31; H01L 23/367

(52) U.S. Cl. CPC H01L 23/49816; H01L 23/3107; H01L 23/3675; H01L 23/49822; H01L 24/08; H01L 24/16; H01L 2224/08146; H01L 2224/08225; H01L 2224/16225; H01L 2224/16227; H01L 2924/1431; H01L 2924/1434; H01L 2924/15311; H01L 2924/182

(57) ABSTRACT

A semiconductor package is provided including: a redistribution substrate having an upper surface and a lower surface, opposite to each other, and including redistribution layers; a semiconductor chip disposed on the upper surface of the redistribution substrate and electrically connected to the redistribution layers; an upper encapsulant encapsulating at least a portion of the semiconductor chip and disposed on the upper surface of the redistribution substrate; a passive component disposed on the lower surface of the redistribution substrate and electrically connected to the redistribution layer; a lower encapsulant encapsulating at least a portion of the passive component and disposed on the lower surface of the redistribution substrate, and having a plurality of openings exposing lowermost redistribution layers among the redistribution layers; and a plurality of bumps respectively disposed within the plurality of openings, the bumps respectively including a first portion in contact with the lowermost redistribution layers and a second portion extending from the first portion and protruding partially downwardly of the plurality of openings.

### CROSS-REFERENCE TO RELATED APPLICATION(S)

This application claims benefit of priority to Korean Patent Application Nos. 10-2022-0134068, filed on Oct. 18, 2022, and 10-2023-0064512, filed on May 18, 2023 in the Korean Intellectual Property Office, the disclosures of which are incorporated herein by reference in their entirety.

### BACKGROUND

The present invention relates to a semiconductor package.

A semiconductor package is often mounted on a substrate (e.g., a main board) through a connection bump (e.g., a solder bump). Connection reliability between the semiconductor package and the substrate is affected by the connection quality between the connection bump and a redistribution layer of the semiconductor package. In order to enhance board level reliability of a semiconductor package, it is helpful to develop a package having excellent connectivity between a redistribution layer and a connection bump.

### SUMMARY

An aspect of the present inventive concept is to provide a semiconductor package having improved yield and reliability.

According to an aspect of the present invention, a semiconductor package is provided, the semiconductor package including a redistribution substrate having an upper surface and a lower surface, opposite to each other, and including a plurality of redistribution layers spaced apart between the upper and lower surfaces; a semiconductor chip disposed on the upper surface of the redistribution substrate, and electrically connected to at least one of the plurality of redistribution layers; an upper encapsulant encapsulating at least a portion of the semiconductor chip and disposed on the upper surface of the redistribution substrate; a passive component disposed on the lower surface of the redistribution substrate, and electrically connected to at least one of the plurality of redistribution layers; a lower encapsulant encapsulating at least a portion of the passive component on the lower surface of the redistribution substrate, and having a plurality of openings exposing lowermost redistribution layers among the plurality of redistribution layers; and a plurality of bumps respectively disposed within the plurality of openings, each of the bumps respectively including a first portion in electrical contact with a lowermost redistribution layer and a second portion below the first portion, the second portion including an outer portion protruding downwardly below its respective opening.

According to an aspect of the present invention, a semiconductor package is provided, the semiconductor package including: a redistribution substrate having an upper surface and a lower surface, opposite to each other, and including a plurality of redistribution layers spaced apart between the upper and lower surfaces; a semiconductor chip disposed on the upper surface of the redistribution substrate, and electrically connected to at least one of the plurality of redistribution layers; an upper encapsulant encapsulating at least a portion of the semiconductor chip and disposed on the upper surface of the redistribution substrate; a passive component disposed on the lower surface of the redistribution substrate, and electrically connected to at least one of the plurality of redistribution layers; a lower encapsulant encapsulating at least a portion of the passive component and disposed on the lower surface of the redistribution substrate, and having a plurality of openings exposing lowermost redistribution layers among the plurality of redistribution layers; and a plurality of bumps respectively disposed within each of the plurality of openings, each of the plurality of bumps respectively including an inner portion surrounded by the lower encapsulant and an outer portion protruding downwardly below the lower encapsulant, wherein the inner and outer portions each have a height perpendicular to the lower surface of the redistribution substrate, and the height of the inner portion is greater than a height of the outer portion.

According to an aspect of the present inventive concept, a semiconductor package is provided, the semiconductor package including: a redistribution substrate having an upper surface and a lower surface, opposite to each other, and including a plurality of redistribution layers spaced apart between the upper and lower surfaces; a semiconductor chip disposed on the upper surface of the redistribution substrate, and electrically connected to the redistribution layers; an upper encapsulant encapsulating at least a portion of the semiconductor chip and disposed on the upper surface of the redistribution substrate; a plurality of passive components and a plurality of bumps disposed on the lower surface of the redistribution substrate and electrically connected to the redistribution layers; and a lower encapsulant covering side surfaces of the plurality of passive components and side surfaces of the plurality of bumps and disposed on the lower surface of the redistribution substrate.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1A is a cross-sectional view illustrating a semiconductor package according to an example embodiment, and FIG. 1B is an enlarged view illustrating region ‘A’ of FIG. 1A;

FIGS. 2A to 2E are views corresponding to FIG. 1B illustrating a portion of a semiconductor package according to example embodiments;

FIGS. 3A to 3F are cross-sectional views illustrating a process of manufacturing a semiconductor package according to an example embodiment of the present inventive concept;

FIG. 4 is a cross-sectional view illustrating a semiconductor package according to an example embodiment of the present inventive concept; and

FIG. 5 is a cross-sectional view illustrating a semiconductor package according to an example embodiment of the present inventive concept.

### DETAILED DESCRIPTION

Hereinafter, with reference to the accompanying drawings, preferred embodiments of the present inventive concept will be described as follows. Unless otherwise specified, spatially relative terms, such as “beneath,” “below,” “lower,” “above,” “upper,” “top,” “bottom,” and the like, may be used herein for ease of description to describe positional relationships, such as illustrated in the figures, for example. It will be understood that the spatially relative terms encompass different orientations of the device in addition to the orientation depicted in the figures, and a lower surface or portion may be described as an upper surface or portion in relation to different elements at a different point in time (e.g., at a different point in a manufacturing process). Furthermore, it will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

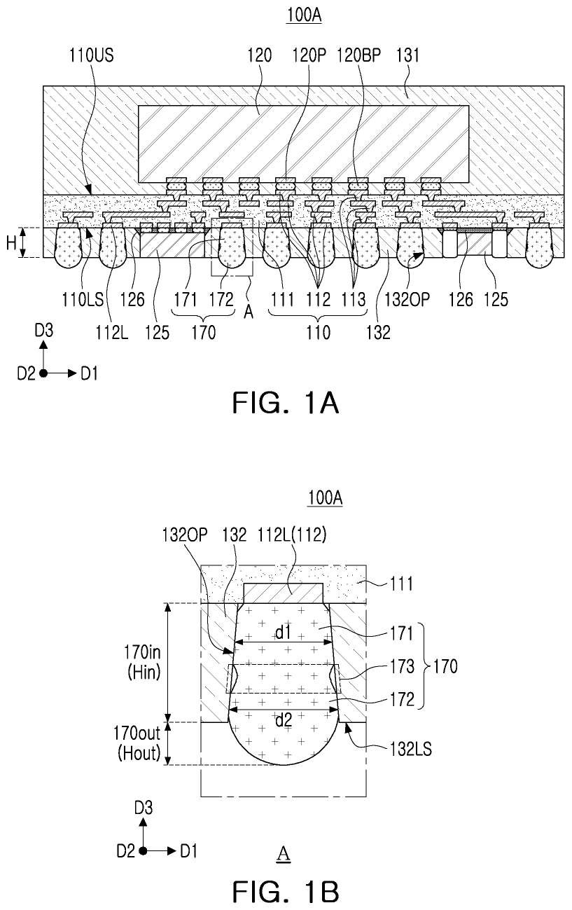

FIG. 1A is a cross-sectional view illustrating a semiconductor package 100A according to an example embodiment, and FIG. 1B is an enlarged view illustrating region ‘A’ in FIG. 1A.

Referring to FIGS. 1A and 1B, the semiconductor package 100A according to an example embodiment may include a redistribution substrate 110, a semiconductor chip 120, one or more passive components 125, an upper encapsulant 131, a lower encapsulant 132, and a plurality of bumps 170.

The redistribution substrate 110 may have an upper surface 110US and a lower surface 110LS, opposite to each other, and may include an insulating layer 111, redistribution layers 112, and redistribution vias 113.

The insulating layer 111 may include an insulating resin. The insulating resin may include or be a thermosetting resin such as an epoxy resin, a thermoplastic resin such as polyimide, or a resin impregnated with an inorganic filler in these resins, for example, prepreg, Ajinomoto Build-up Film (ABF), FR-4 (a flame retardant, woven glass epoxy resin), BT (bismaleimide triazine), and the like. For example, the insulating layer 111 may include or be a photosensitive resin such as a photo-imageable dielectric (PID). In this case, the insulating layer 111 may be formed especially thinly, and further finer redistribution layers 112 and redistribution vias 113 may be formed. The insulating layer 111 may include a plurality of insulating layers 111 stacked in a vertical direction D3. Depending on the process, a boundary between the plurality of insulating layers 111 on different levels may be unclear.

The redistribution layers 112 may include or be formed of, for example, a metal material such as copper (Cu), aluminum (Al), silver (Ag), tin (Sn), gold (Au), nickel (Ni), lead (Pb), titanium (Ti), or alloys thereof. For example, the redistribution layers 112 may include a ground pattern, a power pattern, and a signal pattern. Here, the signal pattern may provide a transmission path for transmitting and receiving various signals other than ground and power, for example, a data or control signal. The redistribution layers 112 may include a plurality of redistribution layers 112 located on different levels in the vertical direction D3. For example, the redistribution layers 112 may include lowermost redistribution layers 112L disposed with a lower surface coplanar with the lower surface 110LS of the redistribution substrate 110. Lowermost redistribution layers 112L may be connected to the passive components 125 and bumps 170. The redistribution layers 112 may be electrically connected to each other through redistribution vias 113.

The redistribution vias 113 may extend vertically within the insulating layer 111 to electrically connect the redistribution layers 112 to each other. The redistribution vias 113 may include a signal via, a ground via, and a power via. The redistribution vias 113 may include or be formed of a metal material, for example, copper (Cu), aluminum (Al), silver (Ag), tin (Sn), gold (Au), nickel (Ni), lead (Pb), titanium (Ti), or alloys thereof. The redistribution vias 113 may be filled vias, in which a via hole is filled with a metal material, or conformal vias, in which a metal material is formed along an inner wall of the via hole.

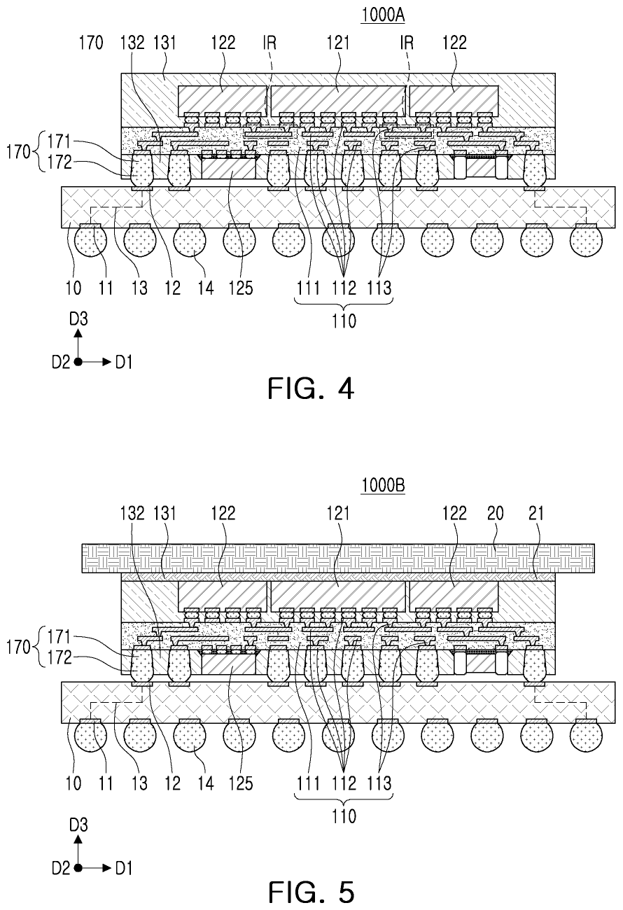

The semiconductor chip 120 may be an integrated circuit (IC) in a bare state, but embodiments are not limited thereto, and the semiconductor chip 120 may also be a package-type integrated circuit. The integrated circuit may be, for example, a processor chip such as a central processor (CPU), a graphics processor (GPU), a field programmable gate array (FPGA), an application processor (AP), a digital signal processor, a cryptographic processor, a microprocessor, a microcontroller, or a logic chip such as an analog-to-digital converter, an application-specific IC (ASIC), and the like, or a memory chip including a volatile memory such as dynamic RAM (DRAM), static RAM (SRAM), and the like, or a non-volatile memory such as phase change RAM (PRAM), magnetic RAM (MRAM), Resistive RAM (RRAM), flash memory, and the like. According to an example embodiment, the semiconductor chip 120 may be provided as multiple semiconductor chips, including different types of integrated circuits (see FIG. 4 and its discussion below).

The semiconductor chip 120 may be disposed on an upper surface 110US of the redistribution substrate HO, and may include connection pads 120P electrically connected to the redistribution layers 112. The connection pads 120P may be connected to the redistribution layers 112 through a conductive structure 120BP. The conductive structure 120BP may include a solder ball, but the present inventive concept is not limited thereto. According to an example embodiment, the conductive structure 120BP may include a pillar portion (not shown) between the connection pad 120P and the solder ball. An underlip layer (not shown) may be disposed between the semiconductor chip 120 and the redistribution substrate 110. The underfill layer may physically and electrically protect the conductive structure 120BP. The underfill layer may have a capillary underfill (CUE) structure, but may also have another structure such as a molded underfill (MTJF) structure integrated with an upper encapsulant 131 according to an example embodiment.

The passive components 125 may be disposed on a lower surface HOLS of the redistribution substrate 110, and electrically connected to the semiconductor chip 120 through the redistribution layers 112. The passive component 125 may improve Signal Integrity (SI) and/or Power Integrity (PI) characteristics of the semiconductor package. The passive component 125 may include or be, for example, a capacitor, an inductor, beads, and the like. A thickness of the passive component 125 may be in a range of about 10 μm to about 100 μm, but embodiments are not necessarily limited to this range. The passive component 125 may not protrude further downwardly of a lower surface 132LS of the lower encapsulant 132. A plurality of passive components 125 may be mounted on the lower surface 110LS of the redistribution substrate 110. According to an example embodiment, the plurality of passive components 125 may have different thicknesses. The passive component 125 may be electrically connected to lowermost redistribution layers 112L through conductive members. An underfill member 126 surrounding the conductive members may be filled between the redistribution substrate 110 and the passive component 125, The underfill member 126 may include or be a polymer material such as an epoxy resin, or the like. According to an example embodiment, the underfill member 126 may be omitted.

The upper encapsulant 131 may encapsulate at least a portion of the semiconductor chip 120 and be disposed on an upper surface 110US of the redistribution substrate 110. The upper encapsulant 131 may include or be, for example, a thermosetting resin such as an epoxy resin, a thermoplastic resin such as polyimide, or a resin impregnated with an inorganic filler, for example, prepreg, ABF, FR-4, BT, or an epoxy molding compound (EMC).

The lower encapsulant 132 may encapsulate at least a portion of the passive component 125 and be disposed on a lower surface 110LS of the redistribution substrate 110. The lower encapsulant 132 may support and fix the passive component 125 and improve connection reliability between the passive component 125 and the redistribution layers 112. Accordingly, the lower encapsulant 132 may be formed to surround a side surface of the passive component 125 and side surfaces of a plurality of bumps 170. The lower encapsulant 132 may be formed to cover the entire side surface of the passive component 125. A height H of the lower encapsulant 132 in a vertical direction D3 may be in a range of about 10 μm to about 150 μm, or of about 50 μm to about 100 μm, but embodiments are not necessarily limited thereto. The lower encapsulant 132 may be formed to a height H capable of covering the side surface of the passive component 125. A lower surface 132LS of the lower encapsulant 132 and a lower surface of the passive component 125 may be coplanar in some embodiments, with the bumps 170 extending vertically through the lower encapsulant at substantially the same level as the passive components 125. According to an example embodiment, the lower encapsulant 132 may cover the lower surface of the passive component 125. For example, at least some of the plurality of passive components 125 may be completely buried in the lower encapsulant 132. The lower encapsulant 132 may include the same material as the upper encapsulant 131. For example, the lower encapsulant 132 and the upper encapsulant 131 may both be EMC.

The lower encapsulant 132 may have a plurality of openings 1320P exposing lowermost redistribution layers 112L. The plurality of openings 1320P may provide a dispositional space for a plurality of bumps 170. According to example embodiments, a plurality of bumps 170 having a higher height than a mounting height of the passive component 125 may be created by stacking solder balls in multiple stages in the plurality of openings 1320P. This lowers difficulty and turnaround time (TAT) and improves board level reliability compared to the case in which a metal post is formed to a predetermined height. Here, the ‘mounting height’ of the passive component 125 means a height including a thickness of the passive component 125 and a gap between the passive component 125 and the redistribution substrate 110.

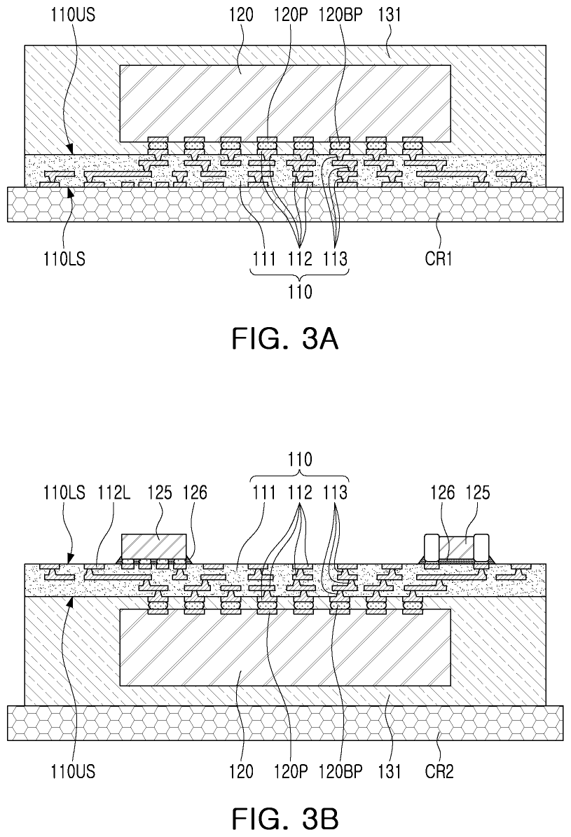

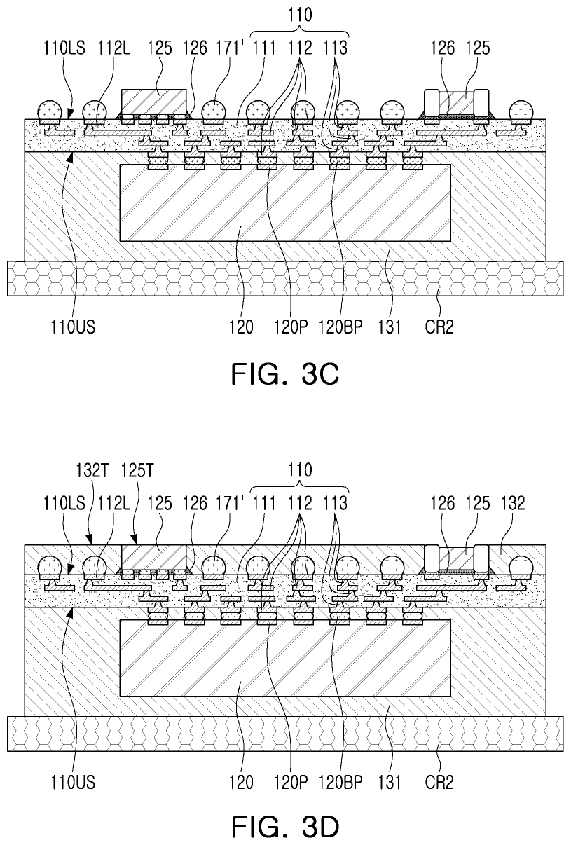

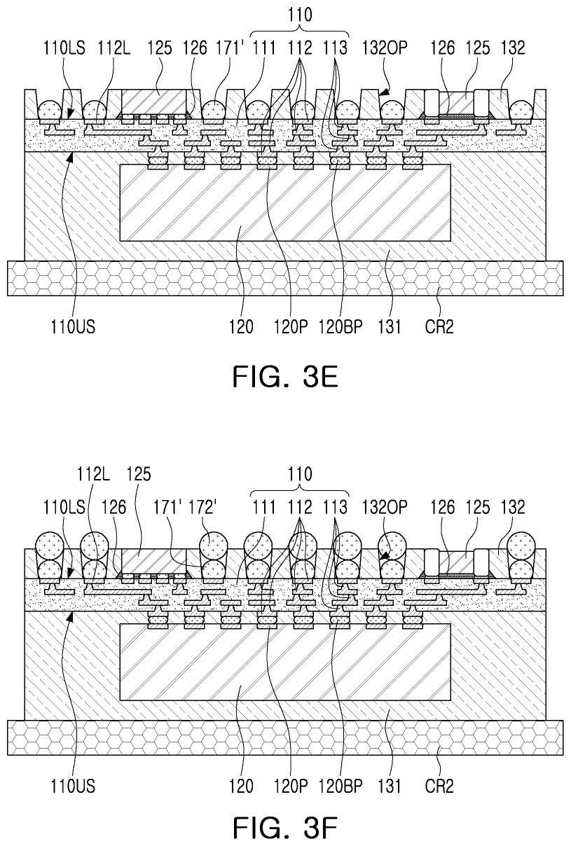

The plurality of bumps 170 may be disposed on a lower surface 110LS of the redistribution substrate 110 and electrically connected to the lowermost redistribution layers 112L (e.g., to contact the lowermost redistribution layers 112L). The semiconductor package 100A may be connected to an external device such as a module substrate, a main board, or the like, through the plurality of bumps 170. The plurality of bumps 170 may include a low-melting point metal, for example, tin (Sn) or an alloy containing tin (e.g., Sn—Ag—Cu). The plurality of bumps 170 may be formed by integrally connecting a plurality of solder balls stacked in the openings 1320P of the lower encapsulant 132 (see FIGS. 3C to 3F and their discussion below). This use of solder balls provides for improved yield and TAT, and board level reliability of the semiconductor package.

The plurality of bumps 170 may be respectively disposed within the plurality of openings 1320P, and each bump 170 may include a first portion 171 in contact with lower redistribution layers 112L and a second portion extending from the first portion 171 and protruding partially downwardly of the plurality of openings 1320P, respectively. The ‘first portion 171’ and the ‘second portion 172’ refer to regions of individual solder balls before melting. After melting, a boundary between the first portion 171 and the second portion 172 may not be clearly visible.

A piece of the second portion 172 may convexly protrude downwardly of the plurality of openings 1320P. For example, referring to FIG. 1B, each of the plurality of bumps 170 may include an inner portion 170in surrounded by the lower encapsulant 132 and an outer portion 170out protruding downwardly of the lower encapsulant 132. A height Hin of the inner portion 170in may be greater than a height Hout of the outer portion 170out.

The first portion 171 and the second portion 172 of each of the plurality of bumps 170 may be integrally connected. At least one of the first portion 171 and the second portion 172 may be in contact with inner walls of the plurality of openings 1320P. In an example embodiment, within the plurality of openings 1320P, a first width d1 of the first portion 171 may be smaller than a second width d2 of the second portion 172. This may be a characteristic due to the shape of the plurality of openings 1320P being tapered toward the lowermost redistribution layer 112L. The first width d1 may be defined as a width of the first portion 171 in contact with inner walls of the plurality of openings 1320P or a maximum width of the first portion 171. The second width d2 may be defined as a width of the second portion 172 in contact with inner walls of the plurality of openings 1320P or a maximum width of the second portion 172.

Each of the plurality of bumps 170 may further include a third portion 173 spaced apart from inner walls of the plurality of openings 132OP. The third portion 173 may be a bonding portion between the first portion 171 and the second portion 172. That is, the third portion 173 may be defined by a bonding region between solder balls. Inner portions 170in of the plurality of bumps 170 may be spaced apart from a region of the inner walls of the plurality of openings 1320P, that is, in the region of the ‘third portion 173’.

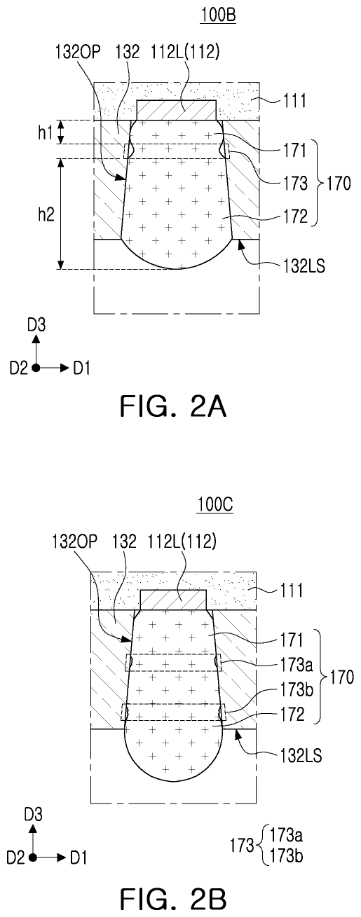

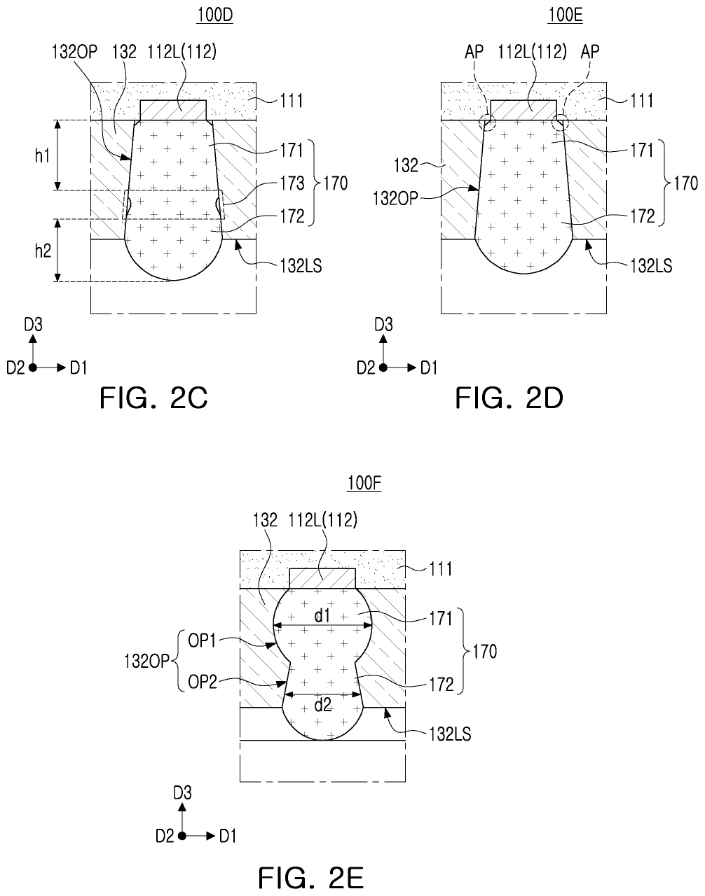

FIGS. 2A to 2E are views illustrating a portion of a semiconductor package according example embodiments. FIGS. 2A to 2E illustrate portions of semiconductor packages corresponding to the region illustrated in FIG. 1B.

Referring to FIG. 2A, a semiconductor package 100B according to an example embodiment may have the same or similar features as those described with reference to FIGS. 1A and 1B. In the embodiment of FIG. 2A, a first height h1 of a first portion 171 of a plurality of bumps 170 may be lower than a second height h2 of a second portion 172 of the plurality of bumps 170. In particular, the first height h1 from an upper end of a third portion 173 of the plurality of bumps 170 to an upper end of the first portion 171 thereof may be lower than the second height h2 from a lower end of the third portion 173 to a lower end of the second portion 172. As described above, the first portion 171 and the second portion 172 may have different heights.

Referring to FIG. 2B, a semiconductor package 100C of an example embodiment have the same or similar features as those described with reference to FIGS. 1A to 2A, except that a plurality of bumps 170 may include two or more regions spaced apart from inner walls of a plurality of openings 1320P. A third portion 173 disposed at least in part between the first portion 171 and the second portion 172 may include two or more regions located on different levels. For example, the third portion 173 may include a first region 173a between the first portion 171 and the second portion 172 and a second region 173b in the middle of the second portion 172. Here, the plurality of bumps 170 may be formed by combining three or more solder balls.

Referring to FIG. 2C, a semiconductor package 100D according to an example embodiment may have the same or similar characteristics to those described with reference to FIGS. 1A to 2B, except that a first height h1 of the first portion 171 of the plurality of bumps 170 is greater than a second height h2 of the second portion 172 of the plurality of bumps 170. The first height h1 of the plurality of bumps 170 from an upper end of a third portion 173 to an upper end of the first portion 171 may be greater than the second height h2 thereof from a lower end of the third portion 173 to a lower end of the second portion 172. As described above, the first portion 171 and the second portion 172 may have different heights.

Referring to FIG. 2D, a semiconductor package 100E according to an example embodiment may have the same or similar features as those described with reference to FIGS. 1A to 2C, except that a plurality of bumps 170 do not include a region spaced apart from inner walls of a plurality of openings 1320P between the first portion 171 and the second portion 172. The plurality of bumps 170 may be in contact with the inner walls of the plurality of openings 1320P, so that a spaced portion between the first portion 171 and the second portion 172, that is the ‘third portion 173’ described above may not be formed. According to example embodiments, an air pocket AP illustrated above the first portion 171 may or may not be formed. The shape of the plurality of bumps 170 inside the plurality of openings 1320P may be variously modified depending on the size of solder balls, reflow process conditions, and the like.

Referring to FIG. 2E, a semiconductor package 100F according to an example embodiment may have the same or similar features as those described with reference to FIGS. 1A to 2D, except that a plurality of openings 1320P include a first inner wall OP1 and a second inner wall OP2. The first inner wall OP1 of the plurality of openings 1320P may have a rounded or convex shape. The second inner wall OP2 of the plurality of openings 1320P may have a tapered shape with a width that decreases toward the first portion 171. Referring to FIGS. 3C to 3E, which are described later, this can be implemented by forming the plurality of openings 1320P to a width that does not completely expose the top portion of first solder balls 171′ in the manufacturing process. In an example embodiment, a maximum width (e.g., first width d1) of the first portion 171 may be greater than a maximum width (e.g., second width d2) of the second portion 172. In another example embodiment (not illustrated in FIGS. 1A to 3E), when a slope of the second inner wall OP2 of the plurality of openings 1320P is large enough so that second width d2 increases sufficiently in the region of the second portion 172 that extends toward the lower surface 132LS of the lower encapsulant 132, the maximum width of the second portion 172 may be greater than that of the first portion 171.

FIGS. 3A to 3F are cross-sectional views illustrating a manufacturing process of a semiconductor package according to an example embodiment. Hereinafter, terms such as ‘upper surface,’ ‘lower surface,’ ‘upper portion,’ ‘lower portion,’ and the like may be referred to based on descriptions and reference numerals referring to FIGS. 1A and 1B.

Referring to FIG. 3A, a first redistribution substrate 110, a semiconductor chip 120, and an upper encapsulant 131 may be disposed on a first carrier CR1. The first carrier CR1 may be, for example, a copper clad laminate (CCL) with which a polymer containing a curable resin and a metal layer containing nickel (Ni), titanium (Ti), or the like, are sequentially coated.

The redistribution substrate 110 may include an insulating layer 111, redistribution layers 112, and redistribution vias 113. The insulating layer 111 may be formed by sequentially applying and curing a photosensitive material, for example, PID. The redistribution layers 112 and the redistribution vias 113 may be created by forming holes penetrating through the insulating layer 111, by performing an exposure process and a development process, and by patterning a metal material on the insulating layer 111 using a plating process.

The semiconductor chip 120 may be mounted on the redistribution substrate 110 in a flip-chip manner. The semiconductor chip 120 may be connected to the redistribution layers 112 through conductive structures 120BP formed on the connection pads 120P. According to an example embodiment, an underfill layer (not shown) may be formed below the semiconductor chip 120.

The upper encapsulant 131 may be formed by applying and curing EMC, for example. According to an example embodiment, a planarization process may be performed on the upper encapsulant 131. The planarization process may include a grinding process, a chemical mechanical polishing (CMP) process, and the like. When the planarization process is performed, an upper surface of the semiconductor chip 120 may be exposed from the upper encapsulant 131.

Referring to FIG. 3B, passive components 125 may be mounted on a lower surface 110LS of the redistribution substrate 110. In order to mount the passive components 125, the redistribution substrate 110 may be inverted using a second carrier CR2. To fix the passive components 125, a reflow process and an underfill process may be performed. An underfill member 126 may be formed below the passive components 125.

Referring to FIG. 3C, first solder balls 171′ may be formed on the lower surface 110LS of the redistribution substrate 110. The first solder balls 171′ may be attached to a redistribution layer (e.g., ‘lowermost redistribution layer 112L’) that has an exposed surface that is substantially coplanar with the lower surface 110LS of the redistribution substrate 110. The first solder balls 171 ‘ may have a smaller diameter than a mounting height of the passive components 125. A reflow process may be performed to fix the first solder balls 171’ to the lowermost redistribution layer 112L′.

Referring to FIG. 3D, a lower encapsulant 132 may be formed on a lower surface 110LS of the redistribution substrate 110. The lower encapsulant 132 may be formed to completely cover the first solder balls 171′. The lower encapsulant 132 may be formed to expose or leave exposed a top surface 125T of the passive components 125. For example, the lower encapsulant 132 may be formed by applying and curing EMC after a mold is brought into close contact with the top surfaces 125T of the passive components 125. The top surface 125T of the passive components 125 and a top surface 132T of the lower encapsulant 132 (referring to the same surface as ‘132LS’ in FIG. 1A) may be coplanar. However, the present inventive concept is not limited thereto, and the lower encapsulant 132 may also be formed to cover the top surfaces 125T of the passive components 125.

Referring to FIG. 3E, a plurality of openings 1320P exposing the first solder balls 171′ may be formed. The plurality of openings 1320P may be formed using physical and/or chemical methods. For example, the plurality of openings 1320P may be formed by removing a portion of the lower encapsulant 132 using a laser drill. In an example embodiment, the plurality of openings 1320P may be formed to have a maximum width greater than the diameter of the first solder balls 171′, but the present invention is not limited thereto.

Referring to FIG. 3F, second solder balls 17 may be attached to the first solder balls 171′. The second solder balls 172′ may be dropped into the plurality of openings 1320P in a pick-and-place manner. In an example embodiment, second solder balls 172′ having the same diameter as the first solder balls 171′ may be attached thereto, but the present invention is not limited thereto, and in some embodiments, the second solder balls 172′ may have a larger or smaller diameter than the first solder balls 171′. Thereafter, the plurality of bumps 170 illustrated in FIGS. 1A and 1B may be formed by performing a reflow process to melt and combine the first solder balls 171′ and the second solder balls 172′. Since the manufacturing process of FIGS. 3A to 3F is performed on a panel or wafer level, the semiconductor package illustrated in FIGS. 1A and 1B may be completed by separating a plurality of unit packages in a sawing process.

FIG. 4 is a cross-sectional view illustrating a semiconductor package 1000A according to an example embodiment.

Referring to FIG. 4, the semiconductor package 1000A according to an example embodiment may have the same or similar features as those described with reference to FIGS. 1A to 3F, except for including a base substrate 10.

The semiconductor package 1000A may include a first semiconductor chip 121 and at least one second semiconductor chip 122 electrically connected to each other through the redistribution layers 112. In an example embodiment, the first semiconductor chip 121 may include or be a logic chip, and the second semiconductor chip 122 may include or be a memory chip. For example, the first semiconductor chip 121 may include or be a central processor (CPU), a graphics processor (GPU), a field programmable gate array (FPGA), an application processor, a digital signal processor, a cryptographic processor, a microprocessor, a microcontroller, an analog-to-digital converter, an ASIC, and the like. For example, the second semiconductor chip 122 may include or be a volatile memory chip such as dynamic RAM (DRAM) or static RAM (SRAM), or a non-volatile memory chip such as phase change RAM (PRAM), magnetic RAM (MRAM), resistive RAM (RRAM), a flash memory, and the like. According to an example embodiment, the second semiconductor chip 122 may be a high-performance memory device such as high bandwidth memory (HBM) or hybrid memory cube (HMC).

According to an example embodiment, the redistribution substrate 110 may further include an interconnection chip (not shown) buried in an interconnection region IR. The interconnection chip (not shown) may be a silicon chip having conductive patterns for transmitting data signals between the first semiconductor chip 121 and the second semiconductor chip 122.

The base substrate 10 may be a package substrate disposed below the redistribution substrate 110, and including an interconnection circuit 13 to which a plurality of bumps 170 are connected. A package substrate may include a printed circuit board (PCB), a ceramic substrate, a glass substrate, a tape wiring board, and the like. The base substrate 10 may include lower pads 11 and upper pads 12. In addition, the base substrate 10 may include an interconnection circuit 13 connected to the lower pads 11 and the upper pads 12 therein. An electrical connection member 14 connected to the lower pad 11 may be disposed below the base substrate 10.

FIG. 5 is a cross-sectional view illustrating a semiconductor package 1000B according to an example embodiment.

Referring to FIG. 5, a semiconductor package 1000B according to an example embodiment may have the same or similar features as those described with reference to FIGS. 1A to 4, except for further including a heat sink 20. The heat sink 20 may be disposed on a first semiconductor chip 121 and a second semiconductor chip 122. The heat sink 20 may prevent warpage of the semiconductor package 1000B, and may dissipate heat transferred from the first semiconductor chip 121 and the second semiconductor chip 122. The heat sink 20 may include a material having excellent thermal conductivity, for example, aluminum (Al), gold (Au), silver (Ag), copper (Cu), iron (Fe), graphite, graphene, or the like. The heat sink 20 may have a plate shape, but the embodiments of the invention are not limited thereto. The heat sink 20 may be attached to the first semiconductor chip 121 and the second semiconductor chip 122 by an insulating thermal conductive layer 21. The insulating thermal conductive layer 21 may include a thermal interface material (TIM) such as a thermally conductive adhesive tape, thermally conductive grease, or thermally conductive adhesive.

As set forth above, according to example embodiments, a semiconductor package having improved yield and reliability may be provided, by stacking solder balls in multiple stages on a lower surface of a redistribution substrate.

The various advantages and effects of the present invention are not limited to the above description. While example embodiments have been shown and described above, it will be apparent to those skilled in the art that modifications and variations could be made without departing from the scope of the present invention, as defined by the appended claims.

What is claimed is:

1. A semiconductor package, comprising:
a redistribution substrate having an upper surface and a lower surface, opposite to each other, and including a plurality of redistribution layers spaced apart between the upper and lower surfaces;
a semiconductor chip disposed on the upper surface of the redistribution substrate, and electrically connected to at least one of the plurality of redistribution layers;
an upper encapsulant encapsulating at least a portion of the semiconductor chip and disposed on the upper surface of the redistribution substrate;
a passive component disposed on the lower surface of the redistribution substrate, and electrically connected to at least one of the plurality of redistribution layers;
a lower encapsulant encapsulating at least a portion of the passive component and disposed on the lower surface of the redistribution substrate, and having a plurality of openings exposing lowermost redistribution layers among the plurality of redistribution layers; and
a plurality of bumps respectively disposed within the plurality of openings, each of the plurality of bumps respectively including a first portion in electrical contact with a lowermost redistribution layer and a second portion below the first portion, the second portion including an outer portion protruding downwardly below its respective opening.

2. The semiconductor package of claim 1, wherein within the plurality of openings, a width of the first portion of a bump is smaller than a width of the second portion of the bump.

3. The semiconductor package of claim 1, wherein at least one of the first portion of a bump and the second portion of the bump is in contact with an inner wall of its respective opening.

4. The semiconductor package of claim 1, wherein the first portion of a bump and the second portion of the bump are both in contact with an inner wall of its respective opening, and wherein each of the plurality of bumps further comprises a third portion disposed between the first and second portions that is spaced apart from the inner wall.

5. The semiconductor package of claim 4, wherein the first, second, and third portions each have an upper end that is its closest point to the lowermost redistribution layer and a lower end that is its farthest point from the lowermost redistribution layer, and the height from the upper end of the third portion to the upper end of the first portion is different from the height from the lower end of the third portion to the lower end of the second portion.

6. The semiconductor package of claim 4, wherein the third portion comprises a first region disposed between the first and second portions and a second region disposed within the second portion, and both the first and second regions are spaced apart from the inner wall.

7. The semiconductor package of claim 1, wherein within the plurality of openings, a maximum width of the first portion is greater than a maximum width of the second portion.

8. The semiconductor package of claim 1, wherein the first portion and the second portion of each of the plurality of bumps are integrally connected.

9. The semiconductor package of claim 1, wherein a lower surface of the lower encapsulant and a lower surface of the passive component are coplanar.

10. The semiconductor package of claim 1, wherein the lower encapsulant covers an entire side surface of the passive component.

11. The semiconductor package of claim 1, wherein a height of the lower encapsulant is in a range of about 10 μm to about 150 μm.

12. The semiconductor package of claim 1, wherein the semiconductor chip comprises a first semiconductor chip and a second semiconductor chip electrically connected to each other through the redistribution substrate.

13. The semiconductor package of claim 12, wherein the first semiconductor chip comprises a logic chip, and
the second semiconductor chip comprises a memory chip.

14. The semiconductor package of claim 12, further comprising:
a base substrate disposed below the redistribution substrate; and including an interconnection circuit to which the plurality of bumps are connected; and
a heat sink disposed on the first semiconductor chip and the second semiconductor chip.

15. A semiconductor package, comprising:
a redistribution substrate having an upper surface and a lower surface, opposite to each other, and including a plurality of redistribution layers spaced apart between the upper and lower surfaces;
a semiconductor chip disposed on the upper surface of the redistribution substrate, and electrically connected to at least one of the plurality of redistribution layers;
an upper encapsulant encapsulating at least a portion of the semiconductor chip and disposed on the upper surface of the redistribution substrate;
a passive component disposed on the lower surface of the redistribution substrate, and electrically connected to at least one of the plurality of redistribution layers;
a lower encapsulant encapsulating at least a portion of the passive component and disposed on the lower surface of the redistribution substrate, and having a plurality of openings exposing lowermost redistribution layers among the plurality of redistribution layers; and
a plurality of bumps respectively disposed within the plurality of openings, each of the plurality of bumps respectively including an inner portion surrounded by the lower encapsulant and an outer portion protruding downwardly below the lower encapsulant,
wherein the inner and outer portions each have a height perpendicular to the lower surface of the redistribution substrate, and the height of the inner portion is greater than the height of the outer portion.

16. The semiconductor package of claim 15, wherein the plurality of bumps comprise tin (Sn) or an alloy of tin (Sn).

17. The semiconductor package of claim 15, wherein the inner portions of the plurality of bumps are spaced apart from inner walls of the plurality of openings in some regions.

18. The semiconductor package of claim 15, wherein the upper encapsulant and the lower encapsulant comprise the same material.

19. A semiconductor package, comprising:
a redistribution substrate having an upper surface and a lower surface, opposite to each other, and including a plurality of redistribution layers spaced apart between the upper and lower surfaces;
a semiconductor chip disposed on the upper surface of the redistribution substrate, and electrically connected to the redistribution layers;
an upper encapsulant encapsulating at least a portion of the semiconductor chip and disposed on the upper surface of the redistribution substrate;
a plurality of passive components and a plurality of bumps disposed on the lower surface of the redistribution substrate and electrically connected to the redistribution layers; and
a lower encapsulant covering side surfaces of the plurality of passive components and side surfaces of the plurality of bumps and disposed on the lower surface of the redistribution substrate.

20. The semiconductor package of claim 19, further comprising:
conductive members electrically connecting the passive components to the redistribution layers; and
an underfill member surrounding the conductive members between the redistribution substrate and the passive components.
